(19) United States
(12) Patent Application Publication
(10) Pub. No.: US 2016/0149096 A1
(43) Pub. Date: May 26, 2016

(54) PROX REACTION APPARATUS FOR FUEL CELL

(71) Applicant: LEDST CO., LTD., Jeollabuk-do (KR)

(72) Inventors: Jong Uk An, Jeollabuk-do (KR); Jeong Hwan Park, Jeollabuk-do (KR); Jai Gon Shim, Gwangju (KR); Noh Joon Park, Jeollabuk-do (KR)

(21) Appl. No.: 14/949,553

(22) Filed: Nov. 23, 2015

Related U.S. Application Data
(60) Provisional application No. 62/083,552, filed on Nov. 24, 2014.

(51) Int. Cl. H01L 33/50; H01L 33/22; H01L 33/32

(52) U.S. Cl. CPC H01L 33/504; H01L 33/32; H01L 33/507; H01L 33/22

(57) ABSTRACT

Provided is a white light emitting diode, which has excellent characteristics by using a UV chip of a specific wavelength band, and red, green blue and yellow phosphors.

### CROSS-REFERENCE TO RELATED APPLICATION

This application claims the benefit of U.S. Patent Application No. 62/083,552 filed on Nov. 24, 2014 in the United States Patent and Trademark Office, the disclosure of which is incorporated herein entirely by reference.

### BACKGROUND OF THE INVENTION

1. Field of the Invention

The following disclosure relates to a white light emitting diode device using a near UV light and a phosphor, and in particular, to a white light emitting diode device using a near UV light and a phosphor, which has a high color rendering index and good light efficiency and is capable of suppressing spikes and IR light components in a blue region.

2. Description of the Related Art

Recently, as a practical technique of an illumination device of a light emitting diode (LED) using a semiconductor light emitting chip, a phosphor is coated on a surface of the semiconductor light emitting diode chip (LED Chip), and phosphor powder is contained in the resin of the LED chip by a predetermined weight %, so that the semiconductor light emitting diode chip gives color lights, for example a white color light, other than its original blue light. An existing illumination device generally uses a GaN-based semiconductor light emitting diode chip which emits a blue color with a peak wavelength of about 460 nm. However, such a white LED includes much blue light, if its spectrum is analyzed, and thus there needs an improvement of optical characteristics such as color stability and color rendering.

### SUMMARY OF THE INVENTION

Such an illumination device using a semiconductor light emitting diode chip causes spots on the illuminated surface due to strong emission frequency of a blue light which is an excited light, which results in bad color stability and thus makes it difficult to obtain a high color rendering index. An embodiment of the present disclosure is directed to providing a white light emitting diode device with an excellent color rendering index and high color stability, which may implement a light emitting spectrum without a halogen lamp to which a daylight filter is mounted, thereby solving the above problem.

In one general aspect, the present disclosure provides a white light emitting diode device which uses a near UV light and a phosphor, the device comprising: a light emitting diode chip having a light emission peak in a wavelength range of 350 nm to 410 nm; and a light emitting unit provided on the light emitting diode chip and excited by light irradiated from the light emitting diode chip, the light emitting unit including four kinds of phosphors as below, which are wavelength-transformed in blue, green, red and yellow regions and dispersed in a silicon resin:
a blue phosphor excitable in a wavelength range of 350 nm to 410 nm and having a main light emission peak in a peak wavelength of 450 nm to 470 nm,
a green phosphor excitable in a wavelength range of 350 nm to 410 nm and having a main light emission peak in a peak wavelength of 510 nm to 550 nm,
a red phosphor excitable in a wavelength range of 350 nm to 410 nm and having a main light emission peak in a peak wavelength of 630 nm to 660 nm, and
a yellow phosphor excitable in a wavelength range of 350 nm to 410 nm and having a main light emission peak in a peak wavelength of 550 nm to 590 nm.

According to an embodiment of the present disclosure, the light emitting diode chip may include a GaN-based crystal layer laminated on a sapphire substrate having unevenness formed on a surface thereof; and a light emitting layer provided on the GaN-based crystal layer, and a light emission wavelength of the light emitting diode chip may have a light emission peak in a wavelength range of 350 nm to 410 nm.

In another aspect, the present disclosure provides a method for obtaining white light-emitting color stability and a high color rendering index by using a semiconductor chip (LED Chip) which emits a near UV light and absorbing near UV rays, mixing three kinds of phosphors including a blue light emitting phosphor for emitting a blue light, a green light emitting phosphor for emitting a green light and a red light emitting phosphor for emitting a red light at a predetermined mixing ratio, thereby giving a color tone similar to natural light or sunlight by inserting a daylight filter (for absorbing a red region from a yellow light by means of a halogen lamp light emission wavelength) into a halogen lamp.

As a method for implementing a light emitting spectrum of a daylight filter halogen lamp, four kinds of wavelength-transformed phosphors are added to blue, green, red and yellow regions excited by light emission from a semiconductor light emitting device, thereby ensuring excellent color stability and a high color rendering index when being irradiated to an article.

In an embodiment of the present disclosure, the LED is selected from the group consisting of a SMD form, a LAMP form and a COB form.

The white light emitting diode device according to the present disclosure ensures an excellent color rendering index and also implements a spectrum of an existing halogen light source. In addition, the white light emitting diode device according to the present disclosure has a high color rendering index and excellent light efficiency and is capable of suppressing spikes and IR light components in a blue region.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 shows an example of an analyzed sunlight spectrum;

FIG. 2 shows an example of an analyzed light emitting spectrum when a daylight filter is mounted to an existing halogen lamp;

FIG. 3 shows an example of an analyzed spectrum of a blue light-excited white LED;

FIG. 4 shows an example of comparative analysis of a light emitting spectrum when a daylight filter is mounted to an existing halogen lamp and a spectrum of a blue light-excited white LED;

FIG. 5 shows an example of measurement analysis of color coordinate, color temperature, color rendering index and light efficiency of a white LED according to an embodiment of the present disclosure;

FIG. 6 shows an example of an analysis result of a spectrum distribution of the white LED according to an embodiment of the present disclosure;

FIG. 7 shows an example of an analysis result of a color coordinate of a white LED having a worm white color with a color temperature of 2,200K to 3,400K according to an embodiment of the present disclosure;

FIG. 8 shows an example of an analysis result of a spectrum of the white LED having a worm white color with a color temperature of 2,200K to 3,400K according to an embodiment of the present disclosure;

FIG. 9 shows an example of an analysis result of a color rendering index of the white LED having a worm white color with a color temperature of 2,200K to 3,400K according to an embodiment of the present disclosure;

FIG. 10 shows an example of an analysis result of a color coordinate of a white LED having a daylight color with a color temperature of 4,500K according to an embodiment of the present disclosure;

FIG. 11 shows an example of an analysis result of a spectrum of the white LED having a daylight color with a color temperature of 4,500K according to an embodiment of the present disclosure;

FIG. 12 shows an example of an analysis result of a color rendering index of the white LED having a daylight color with a color temperature of 4,500K according to an embodiment of the present disclosure;

FIG. 13 shows an example of an analysis result of a color coordinate of a white LED having a cool daylight color with a color temperature of 6,500K according to an embodiment of the present disclosure;

FIG. 14 shows an example of an analysis result of a spectrum of the white LED having a cool daylight color with a color temperature of 6,500K according to an embodiment of the present disclosure; and

FIG. 15 shows an example of an analysis result of a color rendering index of the white LED having a cool daylight color with a color temperature of 6,500K according to an embodiment of the present disclosure.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

Hereinafter, embodiments of the present disclosure will be described in detail.

In order to solve the above problem, the present disclosure provides a white light emitting diode device which uses a near UV light and a phosphor.

The white light emitting diode device using a near UV light and a phosphor according to an embodiment of the present disclosure includes a light emitting diode chip having a light emission peak in a wavelength range of 350 nm to 410 nm, and a light emitting unit provided on the light emitting diode chip and excited by light irradiated from the light emitting diode chip, the light emitting unit including four kinds of phosphors as below, which are wavelength-transformed in blue, green, red and yellow regions and dispersed in a silicon resin:
a blue phosphor excitable in a wavelength range of 350 nm to 410 nm and having a main light emission peak in a peak wavelength of 450 nm to 470 nm,
a green phosphor excitable in a wavelength range of 350 nm to 410 nm and having a main light emission peak in a peak wavelength of 510 nm to 550 nm,
a red phosphor excitable in a wavelength range of 350 nm to 410 nm and having a main light emission peak in a peak wavelength of 630 nm to 660 nm, and
a yellow phosphor excitable in a wavelength range of 350 nm to 410 nm and having a main light emission peak in a peak wavelength of 550 nm to 590 nm.

In particular, the white light emitting diode device using a near UV light and a phosphor according to an embodiment of the present disclosure allows fabrication of a white light emitting diode device with an excellent color rendering index without using an expensive daylight filter.

The light emitting diode chip according to an embodiment of the present disclosure includes a GaN-based crystal layer laminated on a sapphire substrate having unevenness formed on a surface thereof, and a light emitting layer provided on the GaN-based crystal layer, and a light emission wavelength of the light emitting diode chip has a light emission peak in a wavelength range of 350 nm to 410 nm.

Hereinafter, features of the white light emitting diode device according to an embodiment of the present disclosure will be described.

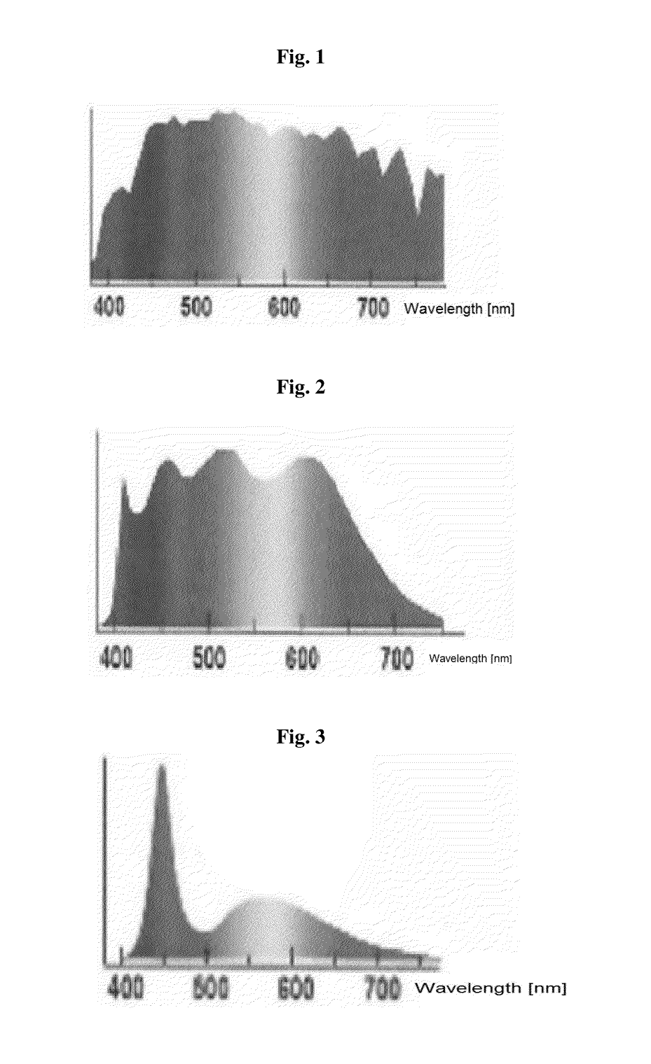

FIG. 1 shows an example of an analyzed sunlight spectrum, and FIG. 2 shows an example of an analyzed light emitting spectrum when a daylight filter is mounted to an existing halogen lamp.

Referring to FIG. 2, it may be found that IR components after a wavelength of 700 nm are removed, but blue spikes are still included.

FIG. 3 shows an example of an analyzed spectrum of a blue light-excited white LED.

Referring to FIG. 3, it may be found that a very large blue spike is included.

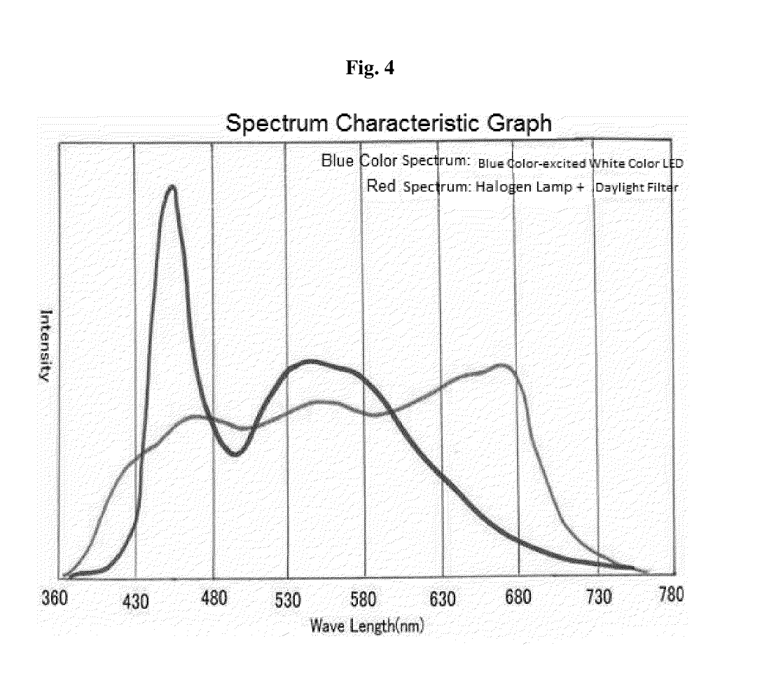

FIG. 4 shows a comparative analysis result of a light emitting spectrum when a daylight filter is mounted to an existing halogen lamp and a spectrum of a blue light-excited white light emitting diode (LED).

Referring to FIG. 4, when a daylight filter is mounted, characteristics similar to the sunlight spectrum may be obtained, but this requires installation of an expensive daylight filter.

Therefore, the present disclosure provides a novel white light emitting diode which ensures an excellent color rendering index and suppresses spikes in a blue region without using such an expensive daylight filter.

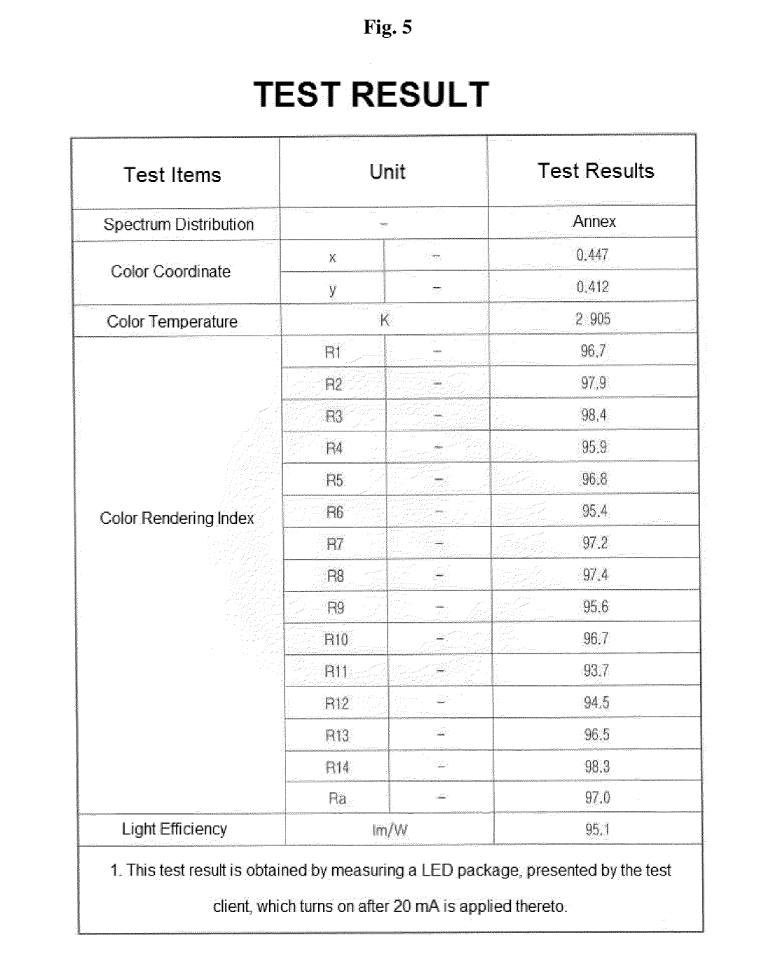

FIG. 5 shows measurement analysis results of color coordinate, color temperature, color rendering index and light efficiency of a white LED according to an embodiment of the present disclosure.

Referring to FIG. 5, it may be found that the white light emitting diode device according to an embodiment of the present disclosure exhibits ultra-high color rendering with an average color rendering index (Ra) of 97 at a color temperature (CCT) of 2905K and also ensures light efficiency of 95 or above.

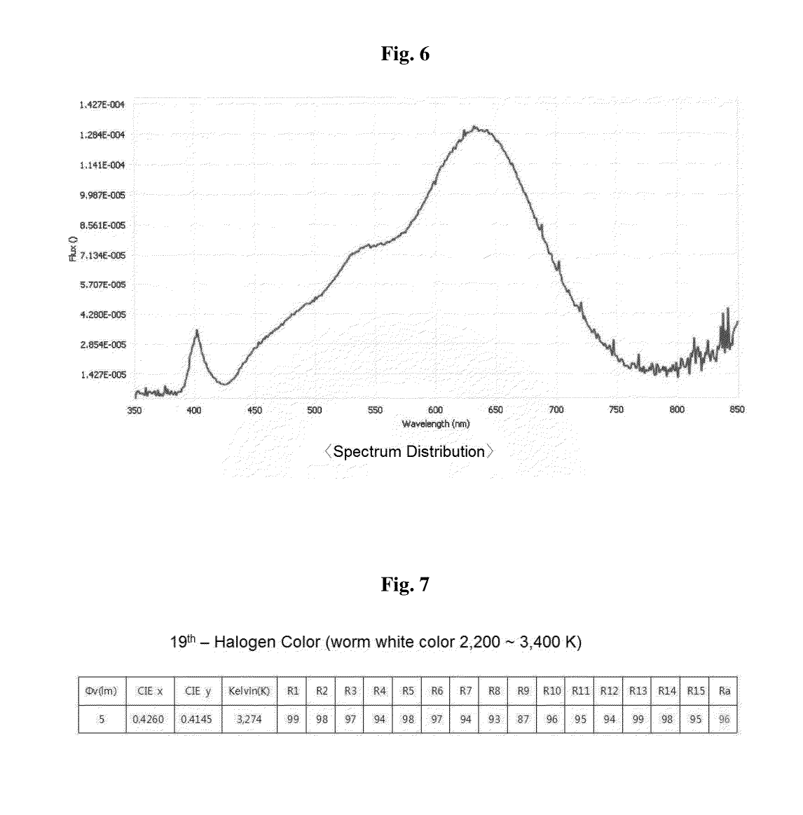

FIG. 6 shows an analysis result of a spectrum distribution of the white LED according to an embodiment of the present disclosure.

Referring to FIG. 6, it may be found that the white LED according to an embodiment of the present disclosure suppresses blue spikes and IR components to the minimum.

FIG. 7 shows an analysis result of a color coordinate of a white LED having a worm white color with a color temperature of 2,200K to 3,400K according to an embodiment of the present disclosure.

Referring to FIG. 7, it may be found that the white LED according to an embodiment of the present disclosure exhibits an average color rendering index (Ra) of 96.

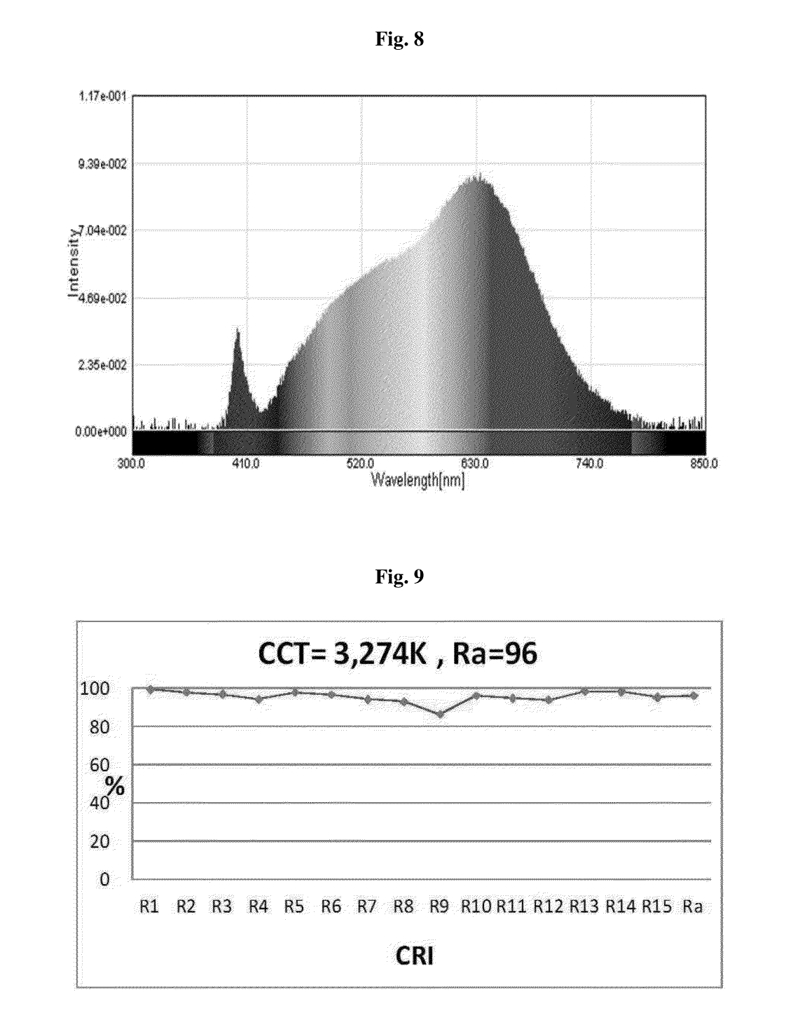

FIG. 8 shows an analysis result of a spectrum of the white LED having a worm white color with a color temperature of 2,200K to 3,400K according to an embodiment of the present disclosure, and FIG. 9 shows an analysis result of a color rendering index of the white LED having a worm white color with a color temperature of 2,200K to 3,400K according to an embodiment of the present disclosure.

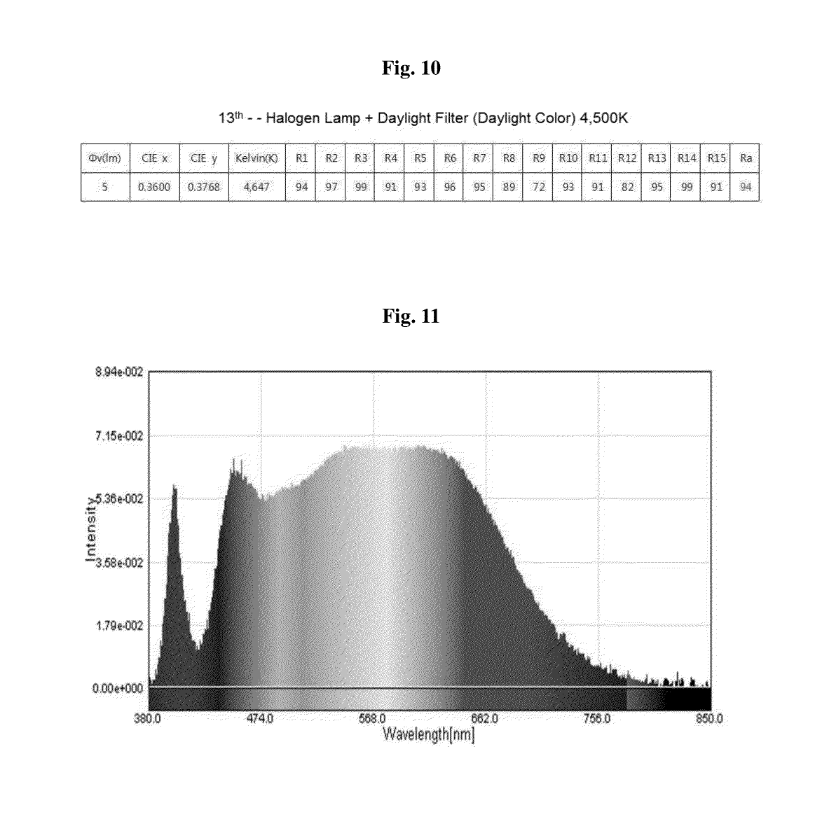

FIG. 10 shows an analysis result of a color coordinate of a white LED having a daylight color with a color temperature of 4,500K according to an embodiment of the present disclosure, and FIG. 11 shows an analysis result of a spectrum of the white LED having a daylight color with a color temperature of 4,500K according to an embodiment of the present disclosure.

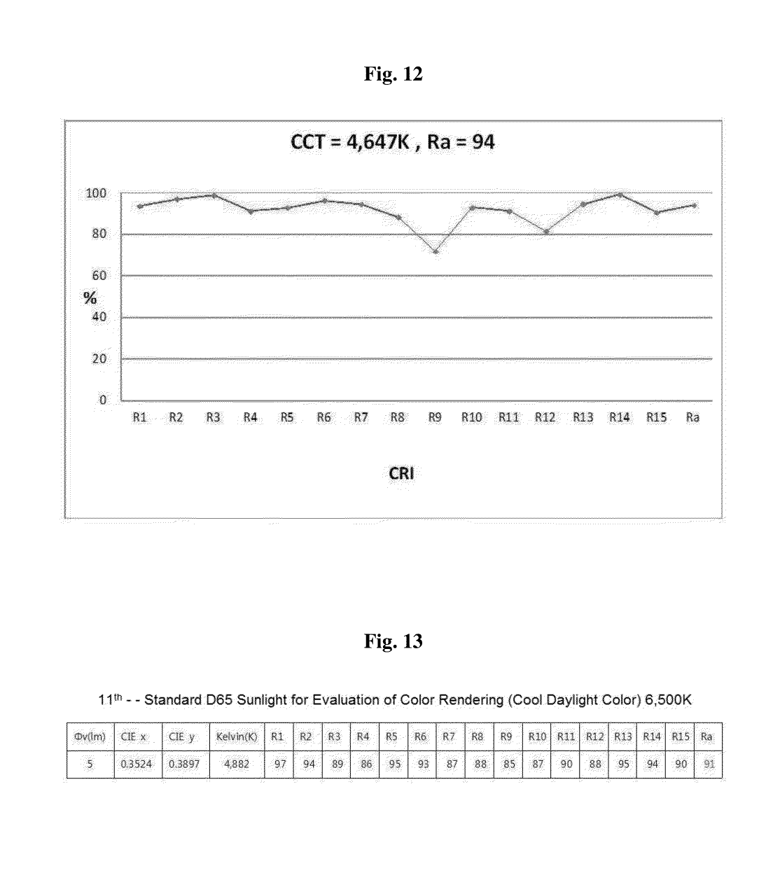

FIG. 12 shows an analysis result of a color rendering index of the white LED having a daylight color with a color temperature of 4,500K according to an embodiment of the present disclosure, and FIG. 13 shows an analysis result of a color coordinate of a white LED having a cool daylight color with a color temperature of 6,500K according to an embodiment of the present disclosure.

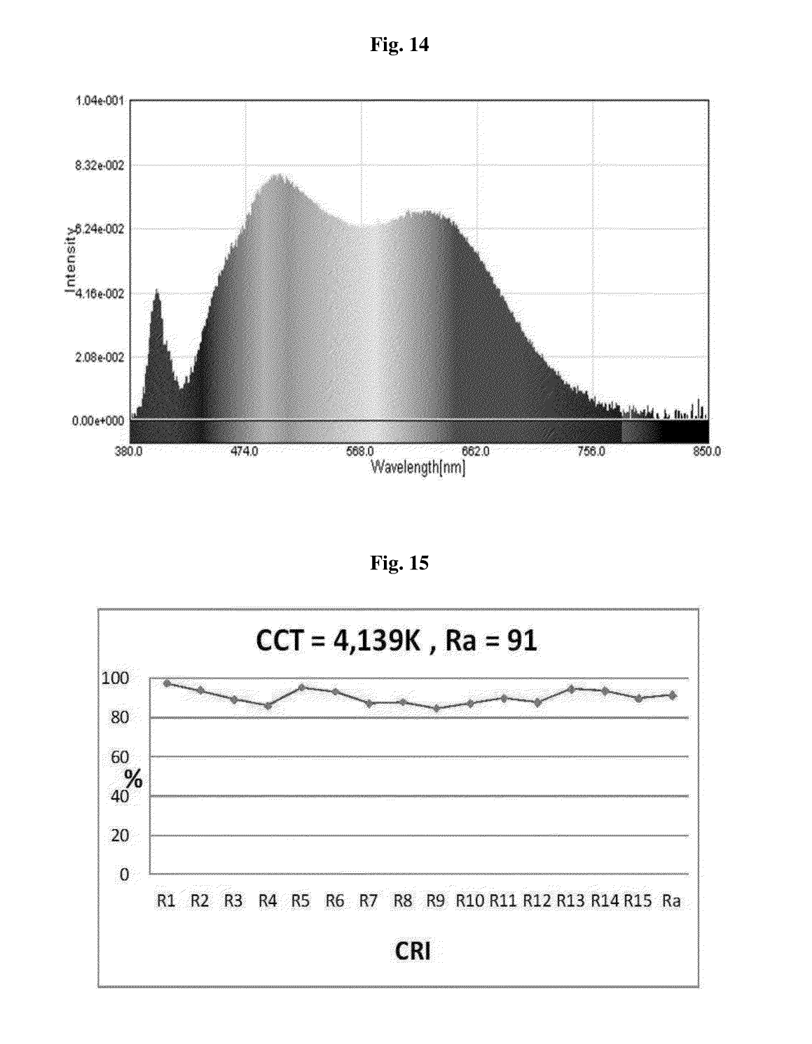

FIG. 14 shows an analysis result of a spectrum of the white LED having a cool daylight color with a color temperature of 6,500K according to an embodiment of the present disclosure, and FIG. 15 shows an analysis result of a color rendering index of the white LED having a cool daylight color with a color temperature of 6,500K according to an embodiment of the present disclosure.

In the present disclosure, a method for mixing three kinds of phosphors including a blue light emitting phosphor for emitting a blue light, a green light emitting phosphor for emitting a green light and a red light emitting phosphor for emitting a red light at a predetermined mixing ratio, by absorbing a near UV light in a UV LED device which emits near UV rays, is proposed and realized to remove spots in white light emission and ensure high color rendering. However, as a measure similar to a light emission spectrum of a daylight filter halogen lamp, the present disclosure also provides an illumination device which ensures improved luster of an illuminated article by adding four kinds of phosphors which are wavelength-transformed in blue, green, red and yellow regions, which are excited due to light emission from the above semiconductor light emitting device.

The above description only exemplifies the technical spirit of the present disclosure, and it will be understood by those skilled in the art to which the present disclosure pertains that various modifications and changes may be made without departing from the essential characteristics of the present disclosure. Accordingly, the embodiments disclosed in the present disclosure are not intended to limit but describe the technical spirit of the present disclosure, and the range of the technical spirit of the present disclosure is not limited by the embodiments. The protection range of the present disclosure should be interpreted by the appended claims, and all technical spirits within the equivalent scope should be interpreted as being included in the scope of the present disclosure.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A white light emitting diode device which uses a near UV light and a phosphor, the device comprising:
a light emitting diode chip having a light emission peak in a wavelength range of 350 nm to 410 nm; and
a light emitting unit provided on the light emitting diode chip and excited by light irradiated from the light emitting diode chip, the light emitting unit including four kinds of phosphors, which are wavelength-transformed in blue, green, red and yellow regions and dispersed in a silicon resin,
wherein the phosphors comprises:
a blue phosphor excitable in a wavelength range of 350 nm to 410 nm and having a main light emission peak in a peak wavelength of 450 nm to 470 nm;
a green phosphor excitable in a wavelength range of 350 nm to 410 nm and having a main light emission peak in a peak wavelength of 510 nm to 550 nm;
a red phosphor excitable in a wavelength range of 350 nm to 410 nm and having a main light emission peak in a peak wavelength of 630 nm to 660 nm; and
a yellow phosphor excitable in a wavelength range of 350 nm to 410 nm and having a main light emission peak in a peak wavelength of 550 nm to 590 nm.

2. The white light emitting diode device of claim 1, wherein the light emitting diode chip comprises:
a GaN-based crystal layer laminated on a sapphire substrate having unevenness formed on a surface thereof; and
a light emitting layer provided on the GaN-based crystal layer,
wherein a light emission wavelength of the light emitting diode chip has a light emission peak in a wavelength range of 350 nm to 410 nm.
